(19) United States
(12) Patent Application Publication
(10) Pub. No.: US 2025/0318416 A1
(43) Pub. Date: Oct. 9, 2025

(54) DISPLAY PANEL AND DISPLAY DEVICE

(71) Applicant: HKC CORPORATION LIMITED, Shenzhen (CN)

(72) Inventors: Yao Li, Shenzhen (CN); Haijiang Yuan, Shenzhen (CN)

(21) Appl. No.: 19/080,913

(22) Filed: Mar. 16, 2025

(30) Foreign Application Priority Data
Apr. 8, 2024 (CN) 202410414554.X

(51) Int. Cl. H10K 59/80; H10K 59/35; H10K 59/38

(52) U.S. Cl. CPC H10K 59/8792; H10K 59/353; H10K 59/38

(57) ABSTRACT

The present application provides a display panel and a display device. The display panel includes a display structure layer, a deformation layer, and a color filter layer stacked in a first direction. The color filter layer comprises an array of color resistance blocks and a light-blocking structures filled between the color resistance blocks. The deformation layer includes an electrorheological deformation body and a light-blocking deformation body stacked in the first direction between the light-blocking structures and the display structure layer. The edges of the electrorheological deformation body and the light-blocking deformation body do not extend beyond the edges of the light-blocking structure. When the color filter layer undergoes deformation, the electrorheological deformation body can deform under the influence of an electric field, compressing the light-blocking deformation body, causing the edges of the light-blocking deformation body to extend outward beyond the edges of the light-blocking structure.

### CROSS REFERENCE TO RELATED APPLICATION

The present application claims priority of a Chinese Patent application, with application No. 202410414554.X, filed on Apr. 8, 2024; the contents of which are incorporated herein by reference.

### TECHNICAL FIELD

The present application relates to the field of display technology, and specifically to a display panel and a display device.

### BACKGROUND

Screen sound device is a display device that arranges an exciter behind the screen, uses the entire screen as a diaphragm, and drives the screen to vibrate through the exciter to achieve sound emission. The screen sound device is becoming increasingly prevalent in daily life due to its strong waterproof property and high space utilization.

The current screen sound devices typically form a color filter layer on an encapsulation layer to replace traditional polarizer, to achieve the objection of reducing the reflectivity and thickness of the display panel.

However, when the screen undergoes sound vibration, the color film layer will deform along with the sound vibration, which causes changing in the light emission angle of the display panel, and results in large viewing angle leakage and color cast, and a decrease in display quality.

### SUMMARY

In view of this, the present application provides a display panel and a display device to improve large viewing angle light leakage and color cast, thereby enhancing the display quality.

In order to achieve the aforementioned objectives, in a first aspect, an embodiment of the present application provides a display panel, which includes: a display structure layer, a deformation layer, and a color filter layer that are stacked in a first direction;
the color filter layer includes color resistance blocks arranged in an array and light-blocking structures filled between the color resistance blocks;
the deformation layer includes an electrorheological deformation body and a light-blocking deformation body stacked between the light-blocking structures and the display structure layer in the first direction; and edges of the electrorheological deformation body and the light-blocking deformation body do not extend beyond edges of the light-blocking structures; and
when the color filter layer deforms, and the electrorheological deformation body enables to deform under an action of an electric field to compress the light-blocking deformation body, such that the edge of the light-blocking deformation body extends outward beyond the edges of the light-blocking structures.

In one possible implementation of the first aspect, the electrorheological deformation body includes a first carbon fiber layer, an electrolyte layer, and a second carbon fiber layer stacked in the first direction, and the first carbon fiber layer and the second carbon fiber layer are doped with conductive ions;
the display panel further includes a controller, the controller is electrically connected to the first carbon fiber layer and the second carbon fiber layer respectively, and the controller is configured to apply a first current to the first carbon fiber layer and the second carbon fiber layer when the color filter layer is deformed, such that an edge of the first carbon fiber layer contracts inward and an edge of the second carbon fiber layer expands outward.

In one possible implementation of the first aspect, the controller is configured to control a direction and a magnitude of a current applied to the first carbon fiber layer and the second carbon fiber layer according to a vibration amplitude and a frequency of the color filter layer, and to further control a degree of contraction of the first carbon fiber layer and a degree of expansion of the second carbon fiber layer.

In one possible implementation of the first aspect, the light-blocking deformation body is a carbon black elastomer, and the light-blocking structures are black matrices.

In one possible implementation of the first aspect, a projection range of the electrorheological deformation body is located within a projection range of the light-blocking deformation body in the first direction.

In one possible implementation of the first aspect, the controller is further configured to:
apply a second current to the first carbon fiber layer and the second carbon fiber layer when the color filter layer returns to a non-deformed state, such that the first carbon fiber layer and the second carbon fiber layer are returned to a non-deformed state, and a direction of the first current is opposite to a direction of the second current.

In one possible implementation of the first aspect, the conductive ions are lithium ions, with a doping concentration of 2% to 5%.

In one possible implementation of the first aspect, a thickness of the electrorheological deformation body in the first direction ranges from 1 μm to 2 μm, and a thickness of the light-blocking deformation body in the first direction ranges from 0.5 μm to 1 μm.

In one possible implementation of the first aspect, areas of the deformation layer, apart from a part of the areas containing the electrorheological deformation body and the light-blocking deformation body, are filled with an organic light-transmitting material.

In a second aspect, an embodiment of the present application provides a display device, which includes: a power supply assembly and the display panel described in the first aspect or any one of the implementations of the first aspect, the power supply assembly is electrically connected to the display panel for supplying power to the display panel.

In the display panel and display device provided in the embodiment of the present application, the display panel includes: the display structure layer, the deformation layer, and the color filter layer that are stacked in the first direction; the color filter layer includes the color resistance blocks arranged in an array and the light-blocking structures filled between the color resistance blocks; the deformation layer includes an electrorheological deformation body and a light-blocking deformation body stacked between the light-blocking structures and the display structure layer in the first direction; and edges of the electrorheological deformation body and the light-blocking deformation body do not extend beyond edges of the light-blocking structures; when the color filter layer deforms, and the electrorheological deformation body enables to deform under an action of an electric field to compress the light-blocking deformation body, such that the edge of the light-blocking deformation body extends outward beyond the edges of the light-blocking structures; therefore the light-blocking width is increased and color mixing between adjacent color resistance blocks is reduced, thus large viewing angle light leakage and color cast are improved, and the display quality is enhanced.

### DESCRIPTION OF DRAWINGS

FIG. 1 is a schematic structural diagram of a display panel provided by an embodiment of the present application;

FIG. 2 is a schematic structural diagram of an electrorheological deformation body provided by an embodiment of the present application;

FIG. 3A is a schematic diagram of light emission angles of a color filter layer in a non-deformed state provided by an embodiment of the present application;

FIG. 3B is a schematic diagram of light emission angles of a color filter layer in a deformed state provided by an embodiment of the present application;

FIG. 4 is a schematic diagram of a deformation layer provided by an embodiment of the present application; and

FIG. 5 is a schematic structural diagram of a display device provided by an embodiment of the present application.

### EXPLANATION OF REFERENCE NUMERALS IN THE DRAWINGS

1—display structure layer; 11—encapsulation layer; 12—cathode layer; 13—organic light-emitting layer; 131—red light-emitting area; 132—green light-emitting area; 133—blue light-emitting area; 14—anode layer;
2—deformation layer; 21—electrorheological deformation body; 211—first carbon fiber layer; 212—electrolyte layer; 213—second carbon fiber layer; 22—light-blocking deformation body;
3—color filter layer; 31—color resistance block; 311—red color resistance block; 312—green color resistance block; 313—blue color resistance block; 32—light-blocking structure; and
100—power supply assembly; 200—display panel.

### DETAILED DESCRIPTION OF THE EMBODIMENTS

The following describes the embodiments of the present application in conjunction with the accompanying drawings. The terms used in the embodiments of the present application are for explaining specific embodiments and are not intended to limit the application. The specific embodiments below can be combined, and for similar concepts or processes, explanations may not be repeated in some embodiments.

Screen sound technology refers to placing several exciters behind the display panel. The exciters convert electrical energy into mechanical energy to generate vibrations transmitted to the display panel, causing the display panel to vibrate and produce sound. When the display panel vibrates and produces sound, the color film layer will deform along with the sound vibration, and the change in the shape of the color film layer will cause the light emission angle from the display panel to change, resulting in large viewing angle leakage and color cast, which in turn leads to a decrease in the display quality of the display panel at large viewing angles.

In view of this, the present application provides a display panel capable of increasing the light emission angles of adjacent color resistance blocks when the color filter layer deforms due to vibrations, thereby the large viewing angle light leakage and the color cast are reduced.

The display panel will be exemplified below in conjunction with specific embodiments and drawings.

FIG. 1 is a schematic structural diagram of the display panel provided by an embodiment of the present application. As shown in FIG. 1, the display panel may include a display structure layer 1, a deformation layer 2, and a color filter layer 3 that are stacked in a first direction. The display structure layer 1 may include, but is not limited to, an encapsulation layer 11, a cathode layer 12, an organic light-emitting layer 13, an anode layer 14, and other structure layers. The organic light-emitting layer 13 is sandwiched between the cathode layer 12 and the anode layer 14, and may include, but is not limited to, a red light-emitting area 131, a green light-emitting area 132, and a blue light-emitting area 133 set in a same layer. Each color-emitting area may contain organic light-emitting materials. When stimulated by the electric field between the cathode layer 12 and the anode layer 14, the organic light-emitting material transitions from a ground state to an excited state and releases energy, to emit light corresponding to the color of the emitting area.

The color filter layer 3 may include color resistance blocks 31 arranged in an array and light-blocking structures 32 filled between the color resistance blocks 31. The color resistance blocks 31 may include a red color resistance block 311, a green color resistance block 312, and a blue color resistance block 313. In some embodiments, the color resistance blocks may also include other colors, such as a white color resistance block. The colors of the color resistance blocks may correspond to the colors of the light-emitting areas in the underlying organic light-emitting layer 13. For example, in the first direction, the red color resistance block 311 may be located within the projection range of the red light-emitting area 131 on the backplane, the green color resistance block 312 within the projection range of the green light-emitting area 132, and the blue color resistance block 313 may be located within the projection range of the blue light-emitting area 133 on the backplane. This arrangement allows each color resistance block to have a high transmission rate, typically 60%, for light of its corresponding color while having a high absorption rate for other colors, thus reducing color mixing.

The light-blocking structures 32 are black matrices, which can reduce natural light reflection and adjust the light emission angle (an acute angle between the emitted light and the organic light-emitting layer 13) of light emitted from the organic light-emitting layer 13, thus the contrast can be improved. In some embodiments, the light-blocking structures 32 may also be formed by stacking the red color resistance block 311, the green color resistance block 312, and the blue color resistance block 313.

In order to facilitate the explanation, the embodiment of the present application provides an exemplary description where the color resistance blocks 31 include the red color resistance block 311, the green color resistance block 312, and the blue color resistance block 313, with the light-blocking structures 32 being black matrices.

As shown in FIG. 1, the deformation layer 2 may include an electrorheological deformation body 21 and a light-blocking deformation body 22. The electrorheological deformation body 21 and the light-blocking deformation body 22 are stacked in the first direction between the light-blocking structures 32 and the display structure layer 1. In the deformation layer 2, areas not occupied by the electrorheological deformation body 21 and the light-blocking deformation body 22 are filled with organic transparent materials. These organic transparent materials can either match the color of the color resistance block above them or be colorless. These materials need to be somewhat stretchable to provide deformation space for the light-blocking deformation body 22.

The light-blocking deformation body 22 can be an elastomer, such as a carbon black elastomer, with shapes that may include, but are not limited to, capsule shaped, block shaped, and irregular shapes, etc. The electrorheological deformation body 21 can deform under the influence of an electric field.

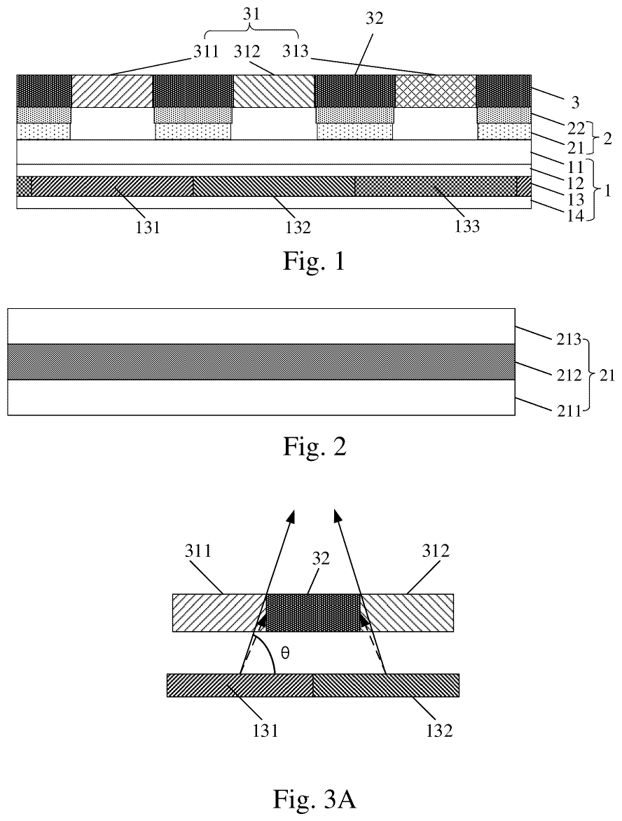

FIG. 2 shows a schematic structure of the electrorheological deformation body provided by an embodiment of the present application. As shown in FIG. 2, the electrorheological deformation body 21 may include a first carbon fiber layer 211, an electrolyte layer 212, and a second carbon fiber layer 213 stacked along the first direction. The first carbon fiber layer 211 and the second carbon fiber layer 213 can be plated with metal layers (not shown) on the sides away from the electrolyte layer 212. The display device can apply a drive current to the electrorheological deformation body 21 through the metal layers, causing the first carbon fiber layer 211 and the second carbon fiber layer 213 to deform under the influence of the electric field.

The carbon fiber layer material has advantages such as being lightweight, high hardness, high structural stability, and strong pressure resistance, thus to effectively improve the lifespan and deformation stability of the electrorheological deformation body 21. When a low voltage DC current is applied to the carbon fiber layer, the following relationship exists between the unloaded potential displacement U, the applied voltage V, and the piezoelectric constant d of the carbon fiber material: U=V×d. This allows for adjusting the applied voltage to change the potential displacement.

The electrolyte layer 212 can be a thin sheet of solid electrolyte. Conductive ions can be doped into the first carbon fiber layer 211 and the second carbon fiber layer 213 to enhance the conductivity of the first carbon fiber layer 211 and the second carbon fiber layer 213 under the electric field. The conductive ions can be cations, such as lithium ions, with a doping concentration of 2%-5%.

The polarity of the conductive ions is related to the bending direction of the electrorheological deformation body 21 under the electric field. For simplicity, lithium ions are used as an example in the following description.

When the color filter layer 3 is undeformed (i.e., in a non-deformed state), the thickness of the electrorheological deformation body 21 in the first direction can range from 1 μm to 2 μm, and the thickness of the light-blocking deformation body 22 can range from 0.5 μm to 1 μm. As shown in FIG. 1, in the second direction, the width of the light-blocking deformation body 22 can be equal to or slightly smaller than the width of the light-blocking structure 32, and the width of the electrorheological deformation body 21 can be equal to or slightly smaller than that of the light-blocking deformation body 22. That is, the edges of the electrorheological deformation body 21 and the light blocking deformation body 22 do not exceed the edge of each of the light-blocking structures 32, and the projection range of the electrorheological deformation body 21 in the first direction falls within the projection range of the light-blocking deformation body 22 in the first direction. This configuration allows light from the light-emitting areas to pass through the corresponding color resistance blocks normally, avoiding any reduction in the pixel display area of the display panel due to the width of the electrorheological deformation body 21 and the light-blocking deformation body 22. The brightness loss in the non-deformed state is reduced, and the brightness of the display panel is improved.

FIGS. 1 and 2 take the first direction as a vertical direction and the second direction as a horizontal direction for exemplary description. It is understood that in some embodiments, the first direction and the second direction may change according to the placement of the display device. For example, the first direction can be the horizontal direction, and the second direction can be the vertical.

In order to improve the accuracy of the applied electric field, in one possible implementation, the display panel may also include a controller (not shown), the controller can be the processor of the display device or an integrated circuit capable of generating control functions within the display device. The controller can be located anywhere within the display device, and this embodiment does not place any particular limitation on the position of the controller. The controller can be electrically connected to the first carbon fiber layer 211 and the second carbon fiber layer 213, for example, via wires. When the color filter layer 3 deforms, the controller can apply a first current to the first carbon fiber layer 211 and the second carbon fiber layer 213.

In an optional implementation, the first current can be a low-voltage direct current, with a voltage range between 0.2V and 1.5V When the controller applies the low-voltage first current to the electrorheological deformation body 21, lithium ions can be migrated from the first carbon fiber layer 211 to the second carbon fiber layer 213 (through the electrolyte layer 212), so that the edge of the first carbon fiber layer 211 can be contracted inward and the edge of the second carbon fiber layer 213 can be extended outward. As a result, the electrorheological deformation body 21 can compress the light-blocking deformation body 22. Even after the first current is removed, the first carbon fiber layer 211 and the second carbon fiber layer 213 can maintain their bent shape due to the migration of the lithium ions, so as to continue to compress the light-blocking deformation body 22.

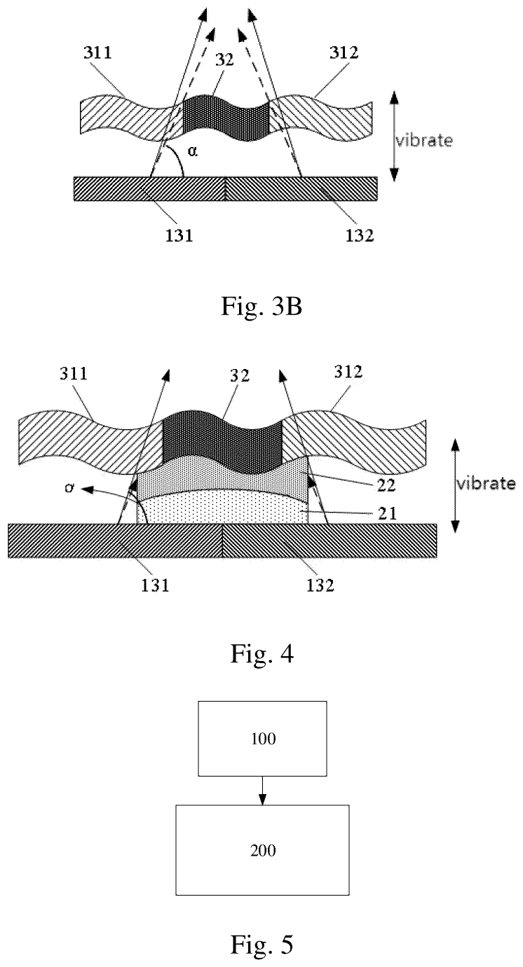

Taking the example where the color filter layer 3 deforms due to vibrations, and the width of the light-blocking structures 32 are decreased in the second direction. As shown in FIGS. 3A and 3B, the solid lines represent the light that can exit out f the display panel when the light-blocking structures 32 are in a non-deformed state, while the dashed line represents the light that is blocked by the light-blocking structures 32 when the light-blocking structures 32 are in a non-deformed state. As shown in FIG. 3A, when the color filter layer 3 is in a non-deformed state, the light emission angle is θ, and the dashed lines are blocked by the light-blocking structures 32, preventing them from exiting out of the display panel. After the width of the light-blocking structures 32 are decreased, as shown in FIG. 3B, the dashed lines originally blocked by the light-blocking structures 32 can now exit out of the display panel due to the decreased width of the light-blocking structures 32; the light emission angle is decreased to a, which results to large viewing angle light leakage and color cast, and the visual experience of the user is reduced.

FIG. 4 illustrates a deformation schematic view of the deformation layer as provided in the embodiments of the present application. As shown in FIG. 4, the electrorheological deformation body 21 in the embodiment can deform under the influence of an electric field, which in turn compresses the light-blocking deformation body 22. This causes the edge of the light-blocking deformation body 22 to extend outward beyond the edges of the light-blocking structures 32. Consequently, even though the width of the light-blocking structures 32 are decreased, the light-blocking width is not decreased because the light-blocking deformation body 22 has a low transmittance. After the color filter layer 3 deforms, the dashed lines of the display panel that can be emitted is still blocked by the light-blocking deformation body 22. At this time, the light emission angle σ being greater than α, therefore, the color mixing between the emitted light of adjacent color filter blocks is reduced and the contrast is improved.

When the color filter layer 3 returns to the non-deformed state, the controller can also apply a second current to the electrorheological deformation body 21, where the current direction of the second current is opposite to that of the first current, and the voltage magnitude may remain the same. When the second current is applied to the electrorheological deformation body 21, the current direction is reversed, and the lithium ions are migrated in the opposite direction, i.e., from the second carbon fiber layer 213 to the first carbon fiber layer 211. This allows the edge of the first carbon fiber layer 211 to expand outward while the edge of the second carbon fiber layer 213 contracts inward. As a result, the electrorheological deformation body 21 can bend in the opposite direction or return to the non-deformed state. This ensures that the electrorheological deformation body 21 does not remain in a bent state for a long time, thus the lifespan of the electrorheological deformation body 21 can be extended.

It is understood that under the same current, the doping concentration of lithium ion will vary, and the contraction and expansion of the first carbon fiber layer 211 and the second carbon fiber layer 213 will differ accordingly. Those skilled in the art can adjust the doping concentration of lithium ions based on actual needs.

In some embodiments, the contraction and expansion of the first carbon fiber layer 211 and the second carbon fiber layer 213 can be adjusted by adjusting the thicknesses of the first carbon fiber layer 211 and the second carbon fiber layer 213. For example, when the first current is applied, the greater the thickness of the first carbon fiber layer 211, the lesser the amount of contraction. Conversely, the smaller the thickness of the first carbon fiber layer 211, the greater the amount of contraction. Those skilled in the art can set the thicknesses of the first carbon fiber layer 211 and the second carbon fiber layer 213 as required to match the expansion of the light-blocking deformation body 22 with the light emission angle.

In another optional implementation, the controller can adjust the direction and magnitude of the current applied to the first carbon fiber layer 211 and the second carbon fiber layer 213 based on the vibration amplitude and frequency of the color filter layer 3, thereby the intensity and direction of the electric field are changed to control the contraction of the first carbon fiber layer 211 and the expansion of the second carbon fiber layer 213. This not only improves the deformation accuracy of the deformation layer 2 but also reduces the power consumption of the display panel.

When the actuator vibrates, the actuator drives the entire display panel to produce a bending vibration, which allows the display panel to push air and generate sound. The greater the vibration amplitude of the display panel, the stronger the sound generated; conversely, the smaller the vibration amplitude, the weaker the sound. Similarly, the higher the vibration frequency, the higher the sound generated, and the lower the vibration frequency, the lower the sound generated.

Exemplarily, considering the switching between non-deformed and deformed states of the display panel during vibration, the controller can increase the magnitude and switching frequency of the first current and the second current when the vibration amplitude and/or frequency of the color filter layer 3 are higher. This allows real-time adjustment of the contraction of the first carbon fiber layer 211 and the expansion of the second carbon fiber layer 213, thereby controlling the bending of the electrorheological deformation body 21 and the expansion of the light-blocking deformation body 22, facilitating real-time adjustment of the light emission angle. This improves the optical efficiency during vibration and enhances the user experience.

Furthermore, since the electrorheological deformation body 21 and the light-blocking deformation body 22 are stacked, and the light-blocking deformation body 22 has a certain degree of elasticity, which effectively reduces the stress between the display structure layer 1, the deformation layer 2, and the color filter layer 3. This buffering effect during vibration of the display panel reduces the risk of film layer breakage and misalignment in the color filter layer 3, therefore the overall structural stability is increased.

The vibration amplitude and frequency of the display panel can be detected using a detection circuit. For example, an acceleration detection circuit can be arranged on the color filter layer 3, when the acceleration of the color filter layer 3 exceeds a preset threshold or when the acceleration direction changes, detection data is sent to the controller, and the controller can then control the intensity and direction of the electric field applied to the first carbon fiber layer 211 and the second carbon fiber layer 213 based on the detection data.

The controller can also obtain the vibration amplitude and frequency of the actuator through the control signal of the actuator, so as to obtain the vibration amplitude and frequency of the display panel. The relationship between vibration amplitude and frequency and the expansion of the carbon fiber layer can be obtained through experimental experience, or fitting empirical formulas from experimental results, or even by analyzing models; which is not specific limited in the present application.

The display panel provided in the embodiment of the present application includes the display structure layer, the deformation layer, and the color filter layer that are stacked in the first direction; the color filter layer includes the color resistance blocks arranged in an array and the light-blocking structures filled between the color resistance blocks; the deformation layer includes an electrorheological deformation body and a light-blocking deformation body stacked between the light-blocking structures and the display structure layer in the first direction; and edges of the electrorheological deformation body and the light-blocking deformation body do not extend beyond edges of the light-blocking structures; when the color filter layer deforms, and the electrorheological deformation body enables to deform under an action of an electric field to compress the light-blocking deformation body, such that the edge of the light-blocking deformation body extends outward beyond the edges of the light-blocking structures; therefore the light-blocking width is increased and color mixing between adjacent color resistance blocks is reduced, thus large viewing angle light leakage and color cast are improved, and the display quality is enhanced.

Based on the same inventive concept, the present application also provides a display device. FIG. 5 illustrates a schematic structure view of the display device as provided in the embodiment of the present application. As shown in FIG. 5, the display device may include a power supply assembly 100 and the aforementioned display panel 200. The power supply assembly 100 is electrically connected to the display panel 200 to supply power to the display panel 200.

Exemplarily, the power supply assembly 100 can be electrically connected to the controller of the display panel 200 to output a first current and/or a second current to the electrorheological deformation body under the control of the controller.

Since the display device in the embodiment includes the display panel from the aforementioned embodiment, the display device possesses all the technical features and effects of the display panel as described in the previous embodiment. For specific details, please refer to the previous embodiment, which will not be repeated here.

It should be understood that in the description of the present application and the appended claims, the terms “comprises,” “includes,” “contains” and any of their variations are intended to cover non-exclusive inclusion, meaning “including but not limited to,” unless specifically emphasized otherwise.

In the description of the present application, unless otherwise specified, the symbol “/” indicates an “or” relationship between the objects it connects. For example, “A/B” can mean A or B; the term “and/or” is used to describe the relationship between associated objects, indicating that there can be three possible relationships, such as A and/or B, which can represent A alone, A and B together, or B alone. A and B can be singular or plural.

Additionally, in the description of the present application, unless otherwise specified, “a plurality of” refers to two or more. “At least one of the following” or similar expressions refer to any combination of these items, including any single or multiple combination.

Furthermore, in the description of the present application, it should be understood that the terms “longitudinal,” “transverse,” “upper,” “lower,” “front,” “rear,” “left,” “right,” “vertical,” “horizontal,” “perpendicular,” “top,” “bottom,” “inner,” “outer,” “axial,” “radial,” “circumferential,” and the like indicating directions or positional relationships are based on the directions or positional relationships shown in the figures. These terms are used solely for convenience in describing the present application and simplifying the description, and are not meant to indicate or imply that the referenced device or element must be oriented in a specific manner or constructed and operated in a particular orientation. Therefore, these terms should not be construed as limitations to the present application.

In the present application, unless otherwise explicitly stated and defined, the terms “connection” and “connected” should be broadly understood. For example, they can refer to mechanical connections, electrical connections, direct connections, or indirect connections through intermediaries. They can refer to communication within two elements or interaction between two elements. Unless otherwise specifically defined, those skilled in the art can understand the specific meanings of these terms within the present application based on the context.

Moreover, in the description of the present application and the appended claims, the terms “first,” “second,” and the like are used to distinguish similar objects and are not necessarily used to describe a specific order or sequence. Nor should they be interpreted as indicating relative importance or implying the quantity of the referenced technical features. It should be understood that such terms can be interchanged where appropriate, allowing the described embodiments to be implemented in orders other than those illustrated or described herein. The features described as “first” and “second” may explicitly or implicitly include at least one of the features.

In the present application, terms like “exemplarily” or “for example” are used to indicate that examples, illustrations, or descriptions are provided for clarity. The embodiments or designs described as “exemplarily” or “for example” should not be interpreted as being preferred or advantageous over other embodiments or designs. Instead, the purpose of using terms like “exemplarily” or “for example” is to present relevant concepts in a specific manner.

In the present application, references to “one embodiment” or “some embodiments” mean that specific features, structures, or characteristics described in connection with the embodiment are included in one or more embodiments of the present application. Therefore, the phrases “in one embodiment,” “in some embodiments,” “in other embodiments,” or “in additional embodiments” that appear in different parts of this description do not necessarily refer to the same embodiment, but rather to “one or more, but not all, embodiments,” unless otherwise specifically emphasized.

Finally, it should be noted that the above embodiments are merely intended to explain the technical solutions of the present application, and are not meant to limit them. Although the present application has been described in detail with reference to the above embodiments, those skilled in the art should understand that modifications to the described technical solutions, or equivalent replacements for some or all of the technical features, may still be made without departing from the scope of the technical solutions of the present application as described in the embodiments.

1. A display panel, comprising:
a display structure layer, a deformation layer, and a color filter layer that are stacked in a first direction;
wherein the color filter layer comprises color resistance blocks arranged in an array and light-blocking structures filled between the color resistance blocks;
wherein the deformation layer comprises an electrorheological deformation body and a light-blocking deformation body stacked between the light-blocking structures and the display structure layer in the first direction; and edges of the electrorheological deformation body and the light-blocking deformation body do not extend beyond edges of the light-blocking structures; and
when the color filter layer deforms, the electrorheological deformation body enables to deform under an action of an electric field to compress the light-blocking deformation body, such that the edge of the light-blocking deformation body extends outward beyond the edges of the light-blocking structures.

2. The display panel according to claim 1, wherein the electrorheological deformation body comprises a first carbon fiber layer, an electrolyte layer, and a second carbon fiber layer stacked in the first direction, wherein the first carbon fiber layer and the second carbon fiber layer are doped with conductive ions;
the display panel further comprises a controller, wherein the controller is electrically connected to the first carbon fiber layer and the second carbon fiber layer respectively, and the controller is configured to apply a first current to the first carbon fiber layer and the second carbon fiber layer when the color filter layer is deformed, such that an edge of the first carbon fiber layer contracts inward and an edge of the second carbon fiber layer expands outward.

3. The display panel according to claim 2, wherein the controller is configured to control a direction and a magnitude of a current applied to the first carbon fiber layer and the second carbon fiber layer according to a vibration amplitude and a frequency of the color filter layer, and to further control a degree of contraction of the first carbon fiber layer and a degree of expansion of the second carbon fiber layer.

4. The display panel according to claim 2, wherein the light-blocking deformation body is a carbon black elastomer, and the light-blocking structures are black matrices.

5. The display panel according to claim 2, wherein a projection range of the electrorheological deformation body is located within a projection range of the light-blocking deformation body in the first direction.

6. The display panel according to claim 2, wherein the controller is further configured to:
apply a second current to the first carbon fiber layer and the second carbon fiber layer when the color filter layer returns to a non-deformed state, such that the first carbon fiber layer and the second carbon fiber layer are returned to a non-deformed state, and a direction of the first current is opposite to a direction of the second current.

7. The display panel according to claim 2, wherein the conductive ions are lithium ions, with a doping concentration of 2% to 5%.

8. The display panel according to claim 2, wherein, a thickness of the electrorheological deformation body in the first direction ranges from 1 μm to 2 μm, and a thickness of the light-blocking deformation body in the first direction ranges from 0.5 μm to 1 μm.

9. The display panel according to claim 1, wherein areas of the deformation layer, apart from a part of the areas containing the electrorheological deformation body and the light-blocking deformation body, are filled with an organic light-transmitting material.

10. The display panel according to claim 2, wherein areas of the deformation layer, apart from a part of the areas containing the electrorheological deformation body and the light-blocking deformation body, are filled with an organic light-transmitting material.

11. The display panel according to claim 3, wherein areas of the deformation layer, apart from a part of the areas containing the electrorheological deformation body and the light-blocking deformation body, are filled with an organic light-transmitting material.

12. The display panel according to claim 4, wherein areas of the deformation layer, apart from a part of the areas containing the electrorheological deformation body and the light-blocking deformation body, are filled with an organic light-transmitting material.

13. The display panel according to claim 5, wherein areas of the deformation layer, apart from a part of the areas containing the electrorheological deformation body and the light-blocking deformation body, are filled with an organic light-transmitting material.

14. The display panel according to claim 6, wherein areas of the deformation layer, apart from a part of the areas containing the electrorheological deformation body and the light-blocking deformation body, are filled with an organic light-transmitting material.

15. The display panel according to claim 7, wherein areas of the deformation layer, apart from a part of the areas containing the electrorheological deformation body and the light-blocking deformation body, are filled with an organic light-transmitting material.

16. The display panel according to claim 8, wherein areas of the deformation layer, apart from a part of the areas containing the electrorheological deformation body and the light-blocking deformation body, are filled with an organic light-transmitting material.

17. A display device, comprising: a power supply assembly and a display panel; and the display panel comprises:
a display structure layer, a deformation layer, and a color filter layer that are stacked in a first direction;
wherein the color filter layer comprises color resistance blocks arranged in an array and light-blocking structures filled between the color resistance blocks;
wherein the deformation layer comprises an electrorheological deformation body and a light-blocking deformation body stacked between the light-blocking structures and the display structure layer in the first direction; and edges of the electrorheological deformation body and the light-blocking deformation body do not extend beyond edges of the light-blocking structures;
when the color filter layer deforms, the electrorheological deformation body enables to deform under an action of an electric field to compress the light-blocking deformation body, such that the edge of the light-blocking deformation body extends outward beyond the edges of the light-blocking structures; and
wherein the power supply assembly is electrically connected to the display panel for supplying power to the display panel.

18. The display device according to claim 17, wherein the electrorheological deformation body comprises a first carbon fiber layer, an electrolyte layer, and a second carbon fiber layer stacked in the first direction, wherein the first carbon fiber layer and the second carbon fiber layer are doped with conductive ions;
the display panel further comprises a controller, wherein the controller is electrically connected to the first carbon fiber layer and the second carbon fiber layer respectively, and the controller is configured to apply a first current to the first carbon fiber layer and the second carbon fiber layer when the color filter layer is deformed, such that an edge of the first carbon fiber layer contracts inward and an edge of the second carbon fiber layer expands outward.

19. The display device according to claim 18, wherein the controller is configured to control a direction and a magnitude of a current applied to the first carbon fiber layer and the second carbon fiber layer according to a vibration amplitude and a frequency of the color filter layer, and to further control a degree of contraction of the first carbon fiber layer and a degree of expansion of the second carbon fiber layer.

20. The display device according to claim 18, wherein the light-blocking deformation body is a carbon black elastomer, and the light-blocking structures are black matrices.
